(19) United States
(12) Patent Application Publication
(10) Pub. No.: US 2025/0149852 A1
(43) Pub. Date: May 8, 2025

(54) PACKAGE ASSEMBLY FOR VERTICAL CAVITY SURFACE EMITTING LASER DEVICE ON A DRIVER IC

(71) Applicant: Lumentum Operations LLC, San Jose, CA (US)

(72) Inventors: Wei SHI, San Jose, CA (US); Yuefa LI, San Jose, CA (US); Kevin WANG, Fremont, CA (US); Siu Kwan CHEUNG, San Jose, CA (US); Lijun ZHU, Dublin, CA (US); Yeyu ZHU, San Jose, CA (US)

(21) Appl. No.: 18/398,522

(22) Filed: Dec. 28, 2023

Related U.S. Application Data
(60) Provisional application No. 63/595,489, filed on Nov. 2, 2023.

(51) Int. Cl. H01S 5/0239; H01S 5/02253; H01S 5/02257; H01S 5/042; H01S 5/183; H01S 5/42

(52) U.S. Cl. CPC H01S 5/0239; H01S 5/02253; H01S 5/02257; H01S 5/042; H01S 5/183; H01S 5/423

(57) ABSTRACT

A package assembly includes a circuit substrate, a top-emitting (TE) vertical cavity surface emitting laser (VCSEL) die having a two-dimensional (2D) matrix addressable emitter array, and a driver integrated circuit (IC) having a flip-chip interconnect configuration. The TE-VCSEL die and the driver IC are coupled together to form a die stack that is mounted to the circuit substrate, with the TE-VCSEL die arranged between the driver IC and the circuit substrate. TE-VCSEL die comprises an optical output arranged at a main surface coupled to the driver IC. The optical output is configured to output light generated by one or more emitters of the emitter array. Thus, the TE-VCSEL die is configured to emit light away from the circuit substrate.

### CROSS-REFERENCE TO RELATED APPLICATION

This Patent Application claims priority to U.S. Provisional Patent Application No. 63/595,489, filed on Nov. 2, 2023, and entitled “PACKAGE ASSEMBLY FOR TOP-EMITTING VERTICAL-CAVITY SURFACE-EMITTING LASER (TE-VCSEL) ON AN INTEGRATED CIRCUIT (IC) DRIVER.” The disclosure of the prior Application is considered part of and is incorporated by reference into this Patent Application.

### TECHNICAL FIELD

The present disclosure relates generally to a package assembly for a TE-VCSEL die and a driver IC die.

### BACKGROUND

A vertical-cavity surface-emitting laser (VCSEL) is a type of semiconductor laser diode (e.g., a laser resonator) with laser beam emission perpendicular to a top surface or a bottom surface of the device. VCSELs typically include two distributed Bragg reflector (DBR) mirrors arranged parallel to a wafer surface with an active region arranged between the two DBR mirrors. The active region includes one or more quantum wells for laser light generation. VCSELs are widely used in various applications, such as data communications, sensing, and optical interconnects, due to advantages over other types of lasers. For example, VCSELs typically have lower power consumption (e.g., VCSELs require much lower power to operate than other types of lasers, making them more energy-efficient and cost-effective), are capable of high-speed operation (e.g., making VCSELs ideal for data communications and other applications that require fast signal transmission), have narrow beam divergence (e.g., the narrow beam divergence of VCSELs allows for high coupling efficiency with optical fibers and other components, making VCSELs easier to integrate into optical systems), and have high reliability (e.g., VCSELs have a long operating lifetime and are less prone to failure than other types of lasers).

Different applications, such as three-dimensional sensing and data communications, may use semiconductor lasers emitting at different wavelength bands. For example, short-range communications may use VCSELs emitting at around 850 nanometer (nm), whereas long-range communications may use VCSELs emitting above 1.3 micrometer (m) or even above 1.5 m. Three-dimensional sensing applications, such as light detection and ranging (LiDAR), may use VCSELs emitting at different wavelengths such as 905 nm and 940 nm to enable varied functions.

A typical VCSEL has a sandwich structure mainly consisting of a top distributed Bragg reflector (DBR), a bottom DBR, and an active region (e.g., an active layer) arranged between the top DBR and the bottom DBR. Each DBR is made of multiple alternatively stacked high-index layers and low-index layers, and each layer has an optical thickness of odd integer of ¼-lambda (¼, ¾, . . . ), where an optical thickness of one lambda is the length of one wavelength divided by the refractive index. “High-index” means a relatively higher value of an optical refractive index, and “low-index” means a relatively lower value of an optical refractive index. Optionally, a DBR may include gradient layers that provide a smoother transition between different energy bands corresponding to high-index and low-index semiconductor materials. The top DBR, the active region, and the bottom DBR form an optical cavity with gain material.

### SUMMARY

In some implementations, a package assembly includes a circuit substrate comprising a first substrate surface and a second substrate surface arranged opposite to the first substrate surface; a top-emitting (TE) VCSEL die arranged on the first substrate surface of the circuit substrate, wherein the TE-VCSEL die comprises an emitter array comprising a plurality of VCSEL emitters that is two-dimensional (2D) matrix addressable, wherein the TE-VCSEL die comprises a first main surface and a second main surface, wherein the first main surface is coupled to the first substrate surface, and the second main surface is arranged opposite to the first main surface, and wherein the TE-VCSEL die comprises an optical output arranged at the second main surface, the optical output configured to output light generated by one or more of the plurality of VCSEL emitters; and a driver integrated circuit (IC) arranged on and coupled to the second main surface of the TE-VCSEL die such that the TE-VCSEL die and the driver IC form a die stack on the first substrate surface of the circuit substrate, wherein the driver IC has a flip-chip interconnect configuration, and wherein the driver IC is electrically coupled to the TE-VCSEL die for individually driving each VCSEL emitter of the plurality of VCSEL emitters according to a 2D matrix address, wherein the driver IC includes a driver substrate comprising a third main surface coupled to the second main surface of the TE-VCSEL die, a fourth main surface arranged opposite to the third main surface, and driver circuitry integrated in the driver substrate, wherein the driver IC includes a first plurality of conductive interconnect structures coupled to the third main surface, wherein the first plurality of conductive interconnect structures include a first subset of conductive interconnect structures electrically coupled to the driver circuitry and the plurality of VCSEL emitters, and a second subset of conductive interconnect structures electrically coupled to the driver circuitry and the circuit substrate.

In some implementations, a method includes attaching a TE-VCSEL die to a driver IC to form a die stack, wherein the TE-VCSEL die comprises an emitter array comprising a plurality of VCSEL emitters, wherein the TE-VCSEL die comprises a first main surface and a second main surface arranged opposite to the first main surface, and wherein the TE-VCSEL die comprises an optical output arranged at the second main surface, the optical output configured to output light generated by one or more of the plurality of VCSEL emitters, wherein the driver IC is coupled to the second main surface of the TE-VCSEL die to form the die stack, wherein the driver IC has a flip-chip interconnect configuration; attaching the TE-VCSEL die to a circuit substrate comprising a first substrate surface and a second substrate surface arranged opposite to the first substrate surface, wherein the first main surface of the TE-VCSEL die is coupled to the first substrate surface of the circuit substrate such that the TE-VCSEL die is arranged between the circuit substrate and the driver IC; and electrically coupling the driver IC to the first substrate surface of the circuit substrate, wherein the driver IC includes a driver substrate comprising a third main surface coupled to the second main surface of the TE-VCSEL die, a fourth main surface arranged opposite to the third main surface, and driver circuitry integrated in the driver substrate, wherein the driver IC includes a first plurality of conductive interconnect structures coupled to the third main surface, wherein the first plurality of conductive interconnect structures include a first subset of conductive interconnect structures electrically coupled to the driver circuitry and the plurality of VCSEL emitters, and a second subset of conductive interconnect structures electrically coupled to the driver circuitry and the circuit substrate.

### BRIEF DESCRIPTION OF THE DRAWINGS

FIGS. 1A and 1B are diagrams depicting a top-view of an example emitter and a cross-sectional view of the example emitter along the line X-X, respectively.

FIG. 2 shows a package assembly according to one or more implementations.

FIG. 3 shows a package assembly according to one or more implementations.

FIG. 4 is a flowchart of an example process associated with fabricating a package assembly for a TE-VCSEL device.

### DETAILED DESCRIPTION

The following detailed description of example implementations refers to the accompanying drawings. The same reference numbers in different drawings may identify the same or similar elements.

A package assembly may include a circuit substrate (e.g., a base substrate), one or more electronic components coupled to and/or embedded in the circuit substrate, and a package casing formed over the circuit substrate to protect (e.g., by encapsulation or partial encapsulation) the one or more electronic components. The one or more electronic components may be interconnected by electrical interconnects to form an electronic system. The electronic components may include one or more dies or chips. A die may be fabricated on a substrate, such as a wafer, and may be or include an unpackaged, bare chip. An integrated circuit (IC) may also be referred to as a die or a chip. For example, an IC may include one or more circuits fabricated on (e.g., integrated on) a piece of semiconductor material (e.g., semiconductor substrate). Thus, an IC may be integrated on a substrate that serves as a carrier for the IC. Thus, the terms die, chip, and IC may be used interchangeably herein.

A package assembly may be referred to as a die package or chip package that includes one or more dies or chips. The package assembly may provide the electronic components and the electrical interconnects with protection from damage and may include a mechanism (such as balls, pins, leads, contact pads, or other electrical interconnect structures) for connecting the electronic components and the electrical interconnects to external components (e.g., a carrier substrate).

A VCSEL die may include a plurality of emitters (e.g., a plurality of VCSEL emitters) integrated on a single die. The VCSEL die may be arranged in a package, such as a package for a time-of-flight (ToF) camera. For example, a top-emitting VCSEL (TE-VCSEL) die may be electrically connected to a driver IC by wire bonds. However, the wire bonds only enable row-by-row control of the plurality of emitters of the TE-VCSEL die. Thus, each emitter of a respective row is collectively enabled or disabled. Row-by-row control may be referred to as one-dimensional (1D) addressability since the plurality of emitters can only be addressed in one dimension. A 1D addressable package assembly may have good thermal performance, but a package size of the 1D addressable package assembly is large.

An array of emitters is two-dimensional (2D) addressable when emitters of the array are addressed (e.g., enabled and disabled) in two dimensions. However, a thermal performance of a package assembly with a 2D matrix addressable array of emitters is typically worse than a thermal performance of a package assembly with a 1D matrix addressable array of emitters. In addition, bottom-emitting (BE)-VCSEL dies are typically used to enable 2D addressing. However, BE-VCSEL dies typically have lower optical efficiency than TE-VCSEL dies.

Some implementations disclosed herein provide a package assembly for a TE-VCSEL die that is 2D addressable. The TE-VCSEL die that is 2D addressable may include emitters that may be addressed (e.g., enabled and disabled) in two dimensions to form a 2D matrix addressable array of emitters. Thus, each emitter may be individually enabled or disabled. A single emitter typically does not provide enough optical power for most ToF applications. As a result, the 2D matrix addressable array of emitters is more practical than a 1D addressable array of emitters, since multiple emitters in a desired zone can be enabled or disabled (powered on or off) simultaneously. The package assembly may include improved thermal paths for dissipating heat generated by the TE-VCSEL die to improve the thermal performance of the TE-VCSEL die. In addition, by using a TE-VCSEL die within the package assembly, an optical efficiency of the package assembly can be improved over package assemblies that use a BE-VCSEL die.

The package assembly may provide high-quality electrical signals, due to short electrical traces between each VCSEL emitter and driver circuitry of a driver IC.

The package assembly may provide a high thermal performance. For example, heat generated by the TE-VCSEL die may be dissipated through a circuit substrate (e.g., a base substrate) of the package assembly rather than through the driver IC. Meanwhile, the driver IC may also have a dedicated thermal path for heat dissipation.

The package assembly may provide a smaller package size relative to, for example, a 1D addressable package assembly.

The package assembly may provide higher light efficiency for an etched silicon (Si) cavity, since a laser beam does not need go through a gallium arsenide (GaAs) substrate, as is the case for a BE-VCSEL.

In comparison to a BE-VCSEL, the package assembly may be more convenient to integrate into an optical device due to an etched Si driver cavity.

The package assembly may provide improved device reliability against moisture penetration due to a front-side surface of the VCSEL emitters (e.g., an optical surface of the emitters) being bonded with a silicon wafer.

For a TE-VCSEL with a wavelength that is 1150 nm or more, a manufacturing process of the package assembly may include copper-copper (Cu-Cu) thermo-compression bonding (TCB) for electrical bonding pads. In addition, the optical surface of the emitters can be bonded by oxides-to-oxides or atomic layer deposition (ALD). This type of diffusion bonding can be achieved in one process. In a light path area, raw silicon material of the driver IC may be artificially left without any IC circuit.

For a TE-VCSEL with wavelength that is less than 1150 nm (or for any wavelength), a manufacturing process of the package assembly may include wet etching a silicon cavity from a backside of a wafer of the driver IC arranged in an optical path of the TE-VCSEL die after an IC circuit of the driver IC is fabricated. An opening dimension of the silicon cavity, located at a bonding area of the TE-VCSEL die, may be easily controlled from a backside of the wafer using a wet etching process due to anisotropic silicon behavior. In addition, a Cu-Cu diffusion bonding may be used to bond the TE-VCSEL die onto the driver IC to provide electrical connections between the TE-VCSEL die onto the driver IC.

In some implementations, a ToF camera is provided that is based on a VCSEL-on-driver technology that includes bonding electrical pads by Cu—Cu diffusion bonding (or gold-gold (Au—Au) diffusion bonding), and bonding an optical surface of the TE-VCSEL die by oxide-oxide bonding (or oxide-nitride bonding) simultaneously, without any bonding interface material at a bond line.

In some implementations, the driver IC has an etched-through window (e.g., an etched-off optical window) to provide an optical path for the TE-VCSEL die.

In some implementations, a bottom surface of the TE-VCSEL die is bonded to a substrate.

In some implementations, the driver IC is electrically connected by a copper-core solder post or a copper-core solder ball.

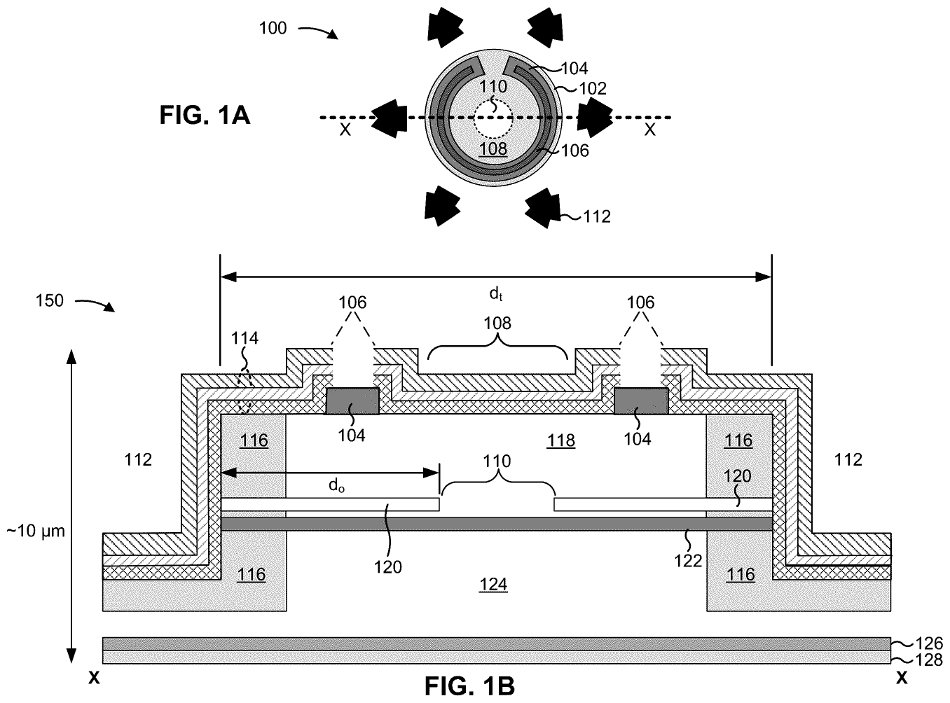

FIGS. 1A and 1B are diagrams depicting a top-view of an example emitter 100 and a cross-sectional view 150 of example emitter 100 along the line X-X, respectively. As shown in FIG. 1A, emitter 100 may include a set of emitter layers constructed in an emitter architecture. In some implementations, emitter 100 may correspond to one or more vertical-emitting devices described herein.

As shown in FIG. 1A, emitter 100 may include an implant protection layer 102 that is circular in shape in this example. In some implementations, implant protection layer 102 may have another shape, such as an elliptical shape, a polygonal shape, or the like. Implant protection layer 102 is defined based on a space between sections of implant material (not shown) included in emitter 100.

As shown by the medium gray and dark gray areas in FIG. 1A, emitter 100 includes an ohmic metal layer 104 (e.g., a P-Ohmic metal layer or an N-Ohmic metal layer) that is constructed in a partial ring-shape (e.g., with an inner radius and an outer radius). The medium gray area shows an area of ohmic metal layer 104 covered by a protective layer (e.g. a dielectric layer or a passivation layer) of emitter 100 and the dark gray area shows an area of ohmic metal layer 104 exposed by via 106, described below. As shown, ohmic metal layer 104 overlaps with implant protection layer 102. Such a configuration may be used, for example, in the case of a P-up/top-emitting emitter 100. In the case of a bottom-emitting emitter 100, the configuration may be adjusted as needed.

Not shown in FIG. 1A, emitter 100 includes a protective layer in which via 106 is formed (e.g., etched). The dark gray area shows an area of ohmic metal layer 104 that is exposed by via 106 (e.g., the shape of the dark gray area may be a result of the shape of via 106) while the medium grey area shows an area of ohmic metal layer 104 that is covered by some protective layer. The protective layer may cover all of the emitter other than the vias. As shown, via 106 is formed in a partial ring-shape (e.g., similar to ohmic metal layer 104) and is formed over ohmic metal layer 104 such that metallization on the protection layer contacts ohmic metal layer 104. In some implementations, via 106 and/or ohmic metal layer 104 may be formed in another shape, such as a full ring-shape or a split ring-shape.

As further shown, emitter 100 includes an optical aperture 108 in a portion of emitter 100 within the inner radius of the partial ring-shape of ohmic metal layer 104. Emitter 100 emits a laser beam via optical aperture 108. As further shown, emitter 100 also includes a current confinement aperture 110 (e.g., an oxide aperture formed by an oxidation layer of emitter 100 (not shown)). Current confinement aperture 110 is formed below optical aperture 108.

As further shown in FIG. 1A, emitter 100 includes a set of trenches 112 (e.g., oxidation trenches) that are spaced (e.g., equally, unequally) around a circumference of implant protection layer 102. How closely trenches 112 can be positioned relative to the optical aperture 108 is dependent on the application, and is typically limited by implant protection layer 102, ohmic metal layer 104, via 106, and manufacturing tolerances.

The number and arrangement of layers shown in FIG. 1A are provided as an example. In practice, emitter 100 may include additional layers, fewer layers, different layers, or differently arranged layers than those shown in FIG. 1A. For example, while emitter 100 includes a set of six trenches 112, in practice, other configurations are possible, such as a compact emitter that includes five trenches 112, seven trenches 112, or another quantity of trenches. In some implementations, trench 112 may encircle emitter 100 to form a mesa structure dt. As another example, while emitter 100 is a circular emitter design, in practice, other designs may be used, such as a rectangular emitter, a hexagonal emitter, an elliptical emitter, or the like. Additionally, or alternatively, a set of layers (e.g., one or more layers) of emitter 100 may perform one or more functions described as being performed by another set of layers of emitter 100, respectively.

Notably, while the design of emitter 100 is described as including a VCSEL, other implementations are possible. For example, the design of emitter 100 may apply in the context of another type of optical device, such as a light emitting diode (LED), or another type of vertical emitting (e.g., top emitting or bottom emitting) optical device. Additionally, the design of emitter 100 may apply to emitters of any wavelength, power level, and/or emission profile. In other words, emitter 100 is not particular to an emitter with a given performance characteristic.

As shown in FIG. 1B, the example cross-sectional view may represent a cross-section of emitter 100 that passes through, or between, a pair of trenches 112 (e.g., as shown by the line labeled “X-X” in FIG. 1A). As shown, emitter 100 may include a backside cathode layer 128, a substrate layer 126, a bottom mirror 124, an active region 122, an oxidation layer 120, a top mirror 118, an implant isolation material 116, a protective layer 114 (e.g. a dielectric passivation/mirror layer), and an ohmic metal layer 104. As shown, emitter 100 may have, for example, a total height that is approximately 10 μm.

Backside cathode layer 128 may include a layer that makes electrical contact with substrate layer 126. For example, backside cathode layer 128 may include an annealed metallization layer, such as an AuGeNi layer, a PdGeAu layer, or the like.

Substrate layer 126 may include a base substrate layer upon which epitaxial layers are grown. For example, substrate layer 126 may include a semiconductor layer, such as a GaAs layer, an InP layer, and/or another type of semiconductor layer.

Bottom mirror 124 may include a bottom reflector layer of emitter 100. For example, bottom mirror 124 may include a distributed Bragg reflector (DBR). Part of the bottom mirror 124 may include a current-blocking DBR that includes alternating p-doped and n-doped layers.

In some implementations, the current-blocking DBR may include an intrinsic layer (i-layer) between p-doped and n-doped layers.

Active region 122 may include a layer that confines electrons and defines an emission wavelength of emitter 100. For example, active region 122 may be a quantum well.

Oxidation layer 120 may include an oxide layer that provides optical and electrical confinement of emitter 100. In some implementations, oxidation layer 120 may be formed as a result of wet oxidation of an epitaxial layer. For example, oxidation layer 120 may be an Al2O3 layer formed as a result of oxidation of an AlAs or AlGaAs layer. Trenches 112 may include openings that allow oxygen (e.g., dry oxygen, wet oxygen) to access the epitaxial layer from which oxidation layer 120 is formed.

Current confinement aperture 110 may include an optically active aperture defined by oxidation layer 120. A size of current confinement aperture 110 may range, for example, from approximately 4 μm to approximately 20 μm. In some implementations, a size of current confinement aperture 110 may depend on a distance between trenches 112 that surround emitter 100. For example, trenches 112 may be etched to expose the epitaxial layer from which oxidation layer 120 is formed. Here, before protective layer 114 is formed (e.g., deposited), oxidation of the epitaxial layer may occur for a particular distance (e.g., identified as do in FIG. 1B) toward a center of emitter 100, thereby forming oxidation layer 120 and current confinement aperture 110. In some implementations, current confinement aperture 110 may include an oxide aperture. Additionally, or alternatively, current confinement aperture 110 may include an aperture associated with another type of current confinement technique, such as an etched mesa, a region without ion implantation, lithographically defined intra-cavity mesa and regrowth, or the like.

Top mirror 118 may include a top reflector layer of emitter 100. For example, top mirror 118 may include a DBR.

Implant isolation material 116 may include a material that provides electrical isolation. For example, implant isolation material 116 may include an ion implanted material, such as a hydrogen/proton implanted material or a similar implanted element to reduce conductivity. In some implementations, implant isolation material 116 may define implant protection layer 102.

Protective layer 114 may include a layer that acts as a protective passivation layer and which may act as an additional DBR. For example, protective layer 114 may include one or more sub-layers (e.g., a dielectric passivation layer and/or a mirror layer, a SiO2 layer, a Si3N4 layer, an Al2O3 layer, or other layers) deposited (e.g., by chemical vapor deposition, atomic layer deposition, or other techniques) on one or more other layers of emitter 100.

As shown, protective layer 114 may include one or more vias 106 that provide electrical access to ohmic metal layer 104. For example, via 106 may be formed as an etched portion of protective layer 114 or a lifted-off section of protective layer 114. Optical aperture 108 may include a portion of protective layer 114 over current confinement aperture 110 through which light may be emitted.

Ohmic metal layer 104 may include a layer that makes electrical contact through which electrical current may flow. For example, ohmic metal layer 104 may include a Ti and Au layer, a Ti and Pt layer and/or an Au layer, or the like, through which electrical current may flow (e.g., through a bond pad (not shown) that contacts ohmic metal layer 104 through via 106). Ohmic metal layer 104 may be P-ohmic, N-ohmic, or other forms known in the art. Selection of a particular type of ohmic metal layer 104 may depend on the architecture of the emitters and is well within the knowledge of a person skilled in the art. Ohmic metal layer 104 may provide ohmic contact between a metal and a semiconductor and/or may provide a non-rectifying electrical junction and/or may provide a low-resistance contact. In some implementations, emitter 100 may be manufactured using a series of steps. For example, bottom mirror 124, active region 122, oxidation layer 120, and top mirror 118 may be epitaxially grown on substrate layer 126, after which ohmic metal layer 104 may be deposited on top mirror 118. Next, trenches 112 may be etched to expose oxidation layer 120 for oxidation. Implant isolation material 116 may be created via ion implantation, after which protective layer 114 may be deposited. Via 106 may be etched in protective layer 114 (e.g., to expose ohmic metal layer 104 for contact). Plating, seeding, and etching may be performed, after which substrate layer 126 may be thinned and/or lapped to a target thickness. Finally, backside cathode layer 128 may be deposited on a bottom side of substrate layer 126.

The number, arrangement, thicknesses, order, symmetry, or the like, of layers shown in FIG. 1B is provided as an example. In practice, emitter 100 may include additional layers, fewer layers, different layers, differently constructed layers, or differently arranged layers than those shown in FIG. 1B. Additionally, or alternatively, a set of layers (e.g., one or more layers) of emitter 100 may perform one or more functions described as being performed by another set of layers of emitter 100 and any layer may comprise more than one layer.

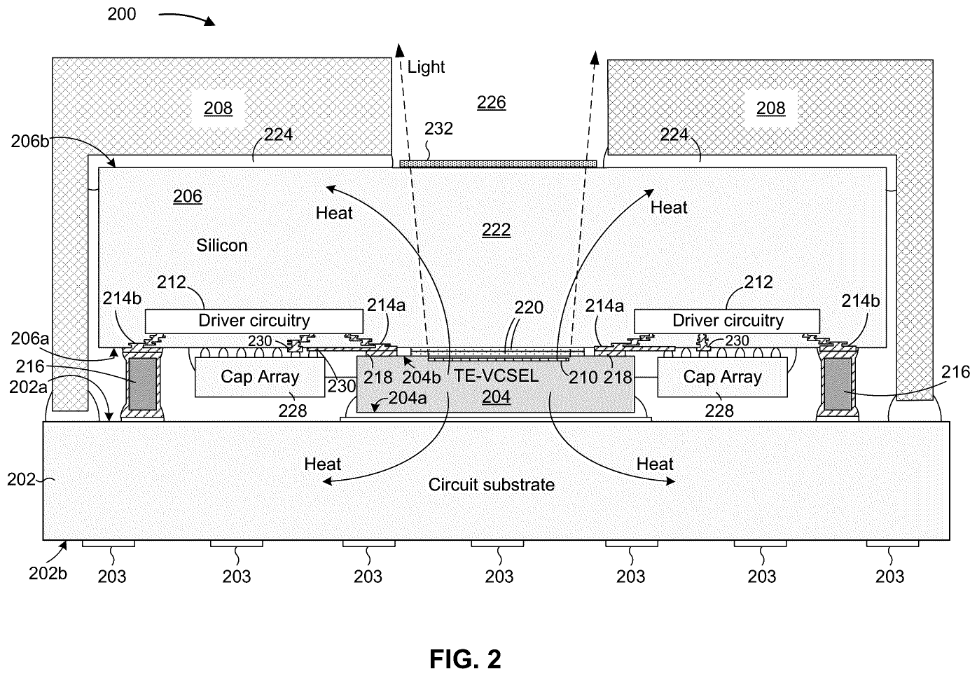

FIG. 2 shows a package assembly 200 according to one or more implementations. The package assembly 200 may be configured for emitters that have an emission wavelength of 1150 nm or more.

The package assembly 200 may include a circuit substrate 202 (e.g., a base substrate), a TE-VCSEL die 204, a driver IC 206 (e.g., a driver die), and a package casing 208.

The circuit substrate 202 may include a first substrate surface 202a (e.g., a top substrate surface) and a second substrate surface 202b (e.g., a bottom substrate surface) arranged opposite to the first substrate surface 202a. The second substrate surface 202b may include a plurality of conductive interconnect structures 203 (e.g., contact pads) for connecting with one or more external components. The first substrate surface 202a may be used for mounting internal components, such as the TE-VCSEL die 204 and the driver IC 206, and the package casings 208 to the circuit substrate 202.

The circuit substrate 202 may be a circuit board, such as a printed circuit board (PCB), a ceramic substrate, or any other substrate configured to provide conductive paths between internal and external components of the package assembly 200. For example, the circuit substrate 202 may be used to provide power signals (e.g., supply signals), information signals, and/or control signals from external components to the internal components of the package assembly 200. Additionally, circuit substrate 202 may be used to provide feedback signals or information signals from the internal components to the external components. In some implementations, the circuit substrate 202 may provide thermal paths for dissipating heat from the TE-VCSEL die 204 and for improving a thermal performance of the TE-VCSEL die 204.

The TE-VCSEL die 204 may be arranged on the first substrate surface 202a of the circuit substrate 202. The TE-VCSEL die 204 may include an emitter array 210 having a plurality of VCSEL emitters that is 2D matrix addressable (e.g., a 2D matrix addressable array of emitters). Each emitter of the emitter array 210 may be a TE-VCSEL emitter, similar to emitter 100. In addition, the TE-VCSEL die 204 may include a first main surface 204a (e.g., a backside surface or bottom surface) and a second main surface 204b (e.g., a frontside surface or top surface). The first main surface 204a may be coupled or otherwise bonded to the first substrate surface 202a, and the second main surface 204b may be arranged opposite to the first main surface 204a. The first main surface 204a may be bonded to the first substrate surface 202a using a non-conductive medium, such as an adhesive or gel. The TE-VCSEL die 204 may include an optical output arranged at the second main surface 204b, with the optical output being configured to output light generated by one or more emitters of the plurality of VCSEL emitters. Thus, an optical aperture of each emitter may be arranged at or proximate to the second main surface 204b, and light may exit the TE-VCSEL die 204 from the second main surface 204b.

The driver IC 206 may be arranged on and coupled to the second main surface 204b of the TE-VCSEL die 204 such that the TE-VCSEL die 204 and the driver IC 206 form a die stack on the first substrate surface 202a of the circuit substrate 202. In addition, the driver IC 206 may have a flip-chip interconnect configuration. As a result, an active area of the driver IC 206 is flipped over facing downward, instead of facing up and bonded to package leads with wires from outside edges of the die. Flip-chip conductive interconnects, such as bumps, balls, or pads, of the driver IC 206 may be provided near the active area, with shorter distances than wire, which greatly reduces inductance and provides improved electrical connections. The driver IC 206 may be electrically coupled (e.g., directly coupled) to the TE-VCSEL die 204 for individually driving each VCSEL emitter of the plurality of VCSEL emitters according to a 2D matrix address. In addition, the flip-chip interconnect configuration may allow the package assembly 200 to be completely devoid of wire bonds. Thus, shorter electrical connections may be used to transmit higher quality signals within the package assembly 200 than would otherwise be possible if wire bonds were used.

The driver IC 206 may include a semiconductor substrate (e.g., silicon) or other driver substrate comprising a third main surface 206a (e.g., a frontside surface or bottom surface) coupled to the second main surface 204b of the TE-VCSEL die 204, a fourth main surface 206b (e.g., a backside surface or top surface) arranged opposite to the third main surface 206a, and driver circuitry 212 integrated in the semiconductor substrate. The driver circuitry 212 may be in one or more active areas of the semiconductor substrate. For example, the driver circuitry 212 may be divided into two or more active areas of the semiconductor substrate in order to reduce a length of electrical connections between the driver circuitry 212 and the TE-VCSEL die 204. The driver circuitry 212 may include a digital control circuit configured to generate driving signals for driving the plurality of VCSEL emitters.

The driver IC 206 may include a first plurality of conductive interconnect structures 214 coupled to the third main surface 206a. The first plurality of conductive interconnect structures 214 may include a first subset of conductive interconnect structures 214a electrically coupled to the driver circuitry 212 and the plurality of VCSEL emitters of the emitter array 210, and a second subset of conductive interconnect structures 214b electrically coupled to the driver circuitry 212 and the circuit substrate 202. Conductive traces (e.g., a series of conductive layers and vias) integrated in the semiconductor substrate may connect the first subset of conductive interconnect structures 214a to the driver circuitry 212. Additionally, additional conductive traces integrated in the semiconductor substrate may connect the second subset of conductive interconnect structures 214b to the driver circuitry 212. Thus, the first subset of conductive interconnect structures 214a may be used to provide driving signals from the driver circuitry 212 to the emitter array 210 for 2D addressable control, and the second subset of conductive interconnect structures 214b may be used to provide signals between the driver circuitry 212 and one or more external components coupled to the circuit substrate 202. For example, the second subset of conductive interconnect structures 214b may be configured to receive power signals and emitter control signals from the circuit substrate 202. The package assembly 200 may include conductive pillars 216 coupled to the second subset of conductive interconnect structures 214b and to the circuit substrate 202. For example, the conductive pillars 216 extend between the circuit substrate 202 and the third main surface 206a of the driver IC 206. The conductive pillars 216 may be copper (Cu) pillars or copper-core solder posts. Alternatively, copper balls or copper-core solder balls may be used instead of conductive pillars 216. The conductive pillars 216 may be used to provide an electrical connection and a mechanical connection between the circuit substrate 202 and the driver IC 206. For example, the conductive pillars 216 may provide structural support to the driver IC 206, which may prevent deformation of the driver IC 206.

The TE-VCSEL die 204 may include a second plurality of conductive interconnect structures 218 arranged at the second main surface 204b of the TE-VCSEL die 204. The second plurality of conductive interconnect structures 218 may be electrically coupled to the first subset of conductive interconnect structures 214a. Thus, the second plurality of conductive interconnect structures 218 may be coupled to the first subset of conductive interconnect structures 214a by metal-to-metal bonding, such as copper-to-copper bonding or gold-to-gold bonding. For example, the second plurality of conductive interconnect structures 218 may be bonded to the first subset of conductive interconnect structures 214a by TCB bonding or another type of diffusion bonding.

The package assembly 200 may include one or more bonding layers 220 (e.g., at least one bonding layer) comprising an inorganic material, such as SiO₂, Al₂O₃, and/or Si₃N₄, wherein the one or more bonding layers 220 are arranged over the emitter array 210 between the TE-VCSEL die 204 and the driver IC 206. Thus, the one or more bonding layers 220 may be arranged over a light path area of the TE-VCSEL die 204, in a light path of emitted light. The one or more bonding layers 220 are configured to bond the second main surface 204b to the third main surface 206a. In some implementations, two bonding layers 220 may be bonded together. The bonding of the two bonding layers 220 and the metal-to-metal bonding used for bonding the second plurality of conductive interconnect structures 218 to the first subset of conductive interconnect structures 214a may be performed simultaneously in a same processing step (e.g., fabrication step). The one or more bonding layers 220 may provide protection to the emitter array 210. For example, the package assembly 200 may provide improved device reliability against moisture penetration due to a frontside surface of the VCSEL emitters (e.g., an optical surface of the emitters) being bonded to the driver IC 206 by the one or more bonding layers 220. Thus, the one or more bonding layers 220 may seal the emitter array 210 from moisture and other particle contaminants.

The TE-VCSEL die 204 may be configured to generate heat during operation. For example, the emitters of the emitter array 210 may generate heat when enabled/activated for light emission. The TE-VCSEL die 204 may be thermally coupled to the circuit substrate 202. Thus, the circuit substrate 202 may be configured to dissipate at least a portion of the heat by one or more thermal paths (e.g., at least one thermal path). Additionally, or alternatively, the TE-VCSEL die 204 may be thermally coupled to the semiconductor substrate of the driver IC 206. Thus, the semiconductor substrate of the driver IC 206 may be configured to dissipate at least a portion of the heat by one or more thermal paths. For example, in some implementations, the semiconductor substrate of the driver IC 206 may be configured to dissipate a first portion of the heat, and the circuit substrate 202 may be configured to dissipate a second portion of the heat. The semiconductor substrate of the driver IC 206 may include a blank semiconductor region 222 arranged over an entire area of the emitter array 210. The blank semiconductor region 222 may be a component-free region of raw semiconductor material configured to receive the first portion of heat and laterally distribute the first portion of heat toward edges of the semiconductor substrate. In some implementations, the blank semiconductor region 222 is configured to distribute the first portion of heat away from the driver circuitry 212 such that the first portion of heat does not degrade a thermal performance of the driver circuitry 212.

The package casing 208 may be bonded to the first substrate surface 202a and may be disposed over (extend over) the die stack. The package casing 208 may be coupled to the fourth main surface 206b of the driver IC with bonding material 224, such as an adhesive or gel. The package casing 208 may include an optical window 226 arranged over the light path area and configured to permit the light generated by the emitter array 210 to exit the package assembly 200.

In some implementations, the semiconductor substrate of the driver IC 206 is optically transparent to the light generated by the emitter array 210. For example, the semiconductor substrate may be optically transparent to light having a wavelength of 1150 nm or greater. In other words, for wavelengths of 1150 nm or greater, a light absorption coefficient of the semiconductor substrate may be sufficiently low that any light absorption would be within acceptable limits for light transmission. For example, the semiconductor substrate may pass at least 95% of the light received from the emitter array 210 for wavelengths of 1150 nm or greater. An amount of light transmitted through the semiconductor substrate may depend on the light absorption coefficient of the semiconductor substrate for a particular wavelength and a thickness of the semiconductor substrate.

The TE-VCSEL die 204 may be configured to transmit the light through a light path area of the semiconductor substrate to the optical window 226. The light path area may coincide with the blank semiconductor region 222. For example, the blank semiconductor region 222 may be arranged over the emitter array 210 in the light path area of the semiconductor substrate. The blank semiconductor region 222, being a component-free region of raw semiconductor material, may be configured to receive the light from the emitter array 210 and pass the light to the optical window 226.

In some implementations, the package assembly 200 may include at least one capacitor (cap) die 228, with each capacitor die 228 including a plurality of capacitors (e.g., a cap array). The driver IC 206 may include a third plurality of conductive interconnect structures 230 coupled to the third main surface 206a. The at least one capacitor die 228 may be coupled to the third main surface 206a of the driver IC 206, and may be electrically coupled to the third plurality of conductive interconnect structures 230. In addition, the plurality of capacitors may be electrically coupled to the emitter array 210 via the third plurality of conductive interconnect structures 230. The plurality of capacitors may be used to supply stable voltages to the driver circuitry 212 and/or the emitter array 210.

In some implementations, an anti-reflection coating 232 may be arranged on the fourth main surface 206b (e.g., a backside or top surface) of the driver IC 206. The anti-reflection coating 232 may be arranged in the light path area (e.g., in a light transmission path). The anti-reflection coating 232 may suppress or attenuate optical substrate modes due to multiple reflections, which may result in a cleaner optical spectral output and/or an optical output with lower noise.

As indicated above, FIG. 2 is provided as an example. Other examples may differ from what is described with regard to FIG. 2. The number and arrangement of devices and components shown in FIG. 2 are provided as an example. In practice, there may be additional devices or components, fewer devices or components, different devices or components, or differently arranged devices or components than those shown in FIG. 2.

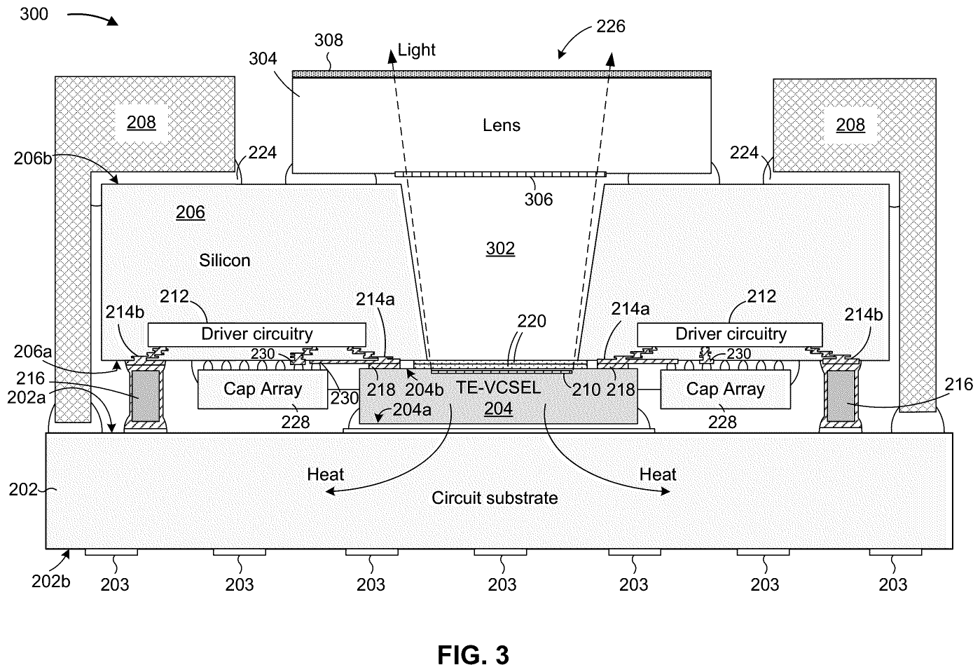

FIG. 3 shows a package assembly 300 according to one or more implementations. The package assembly 300 may be configured for emitters that have an emission wavelength of any wavelength, including a wavelength less than 1150 nm. For example, the light absorption coefficient of the semiconductor substrate may be sufficiently high for wavelengths less than 1150 nm that any light absorption may not be within acceptable limits for light transmission.

The package assembly 300 may be similar to the package assembly 200, with an exception that the semiconductor substrate includes a cavity 302 arranged over the light path area of the emitter array 210 (e.g., in the light path area of the semiconductor substrate of the driver IC 206) and includes a lens 304 arranged over the light path area of the emitter array 210 and over the light path area of the semiconductor substrate.

The cavity 302 may extend through the semiconductor substrate between the third main surface 206a and the fourth main surface 206b. Thus, the TE-VCSEL die 204 may be configured to transmit light through the cavity 302 to the optical window 226. The cavity 302 may be encircled by the semiconductor material of the semiconductor substrate. Portions of the driver IC 206 at edges of the cavity 302 may be bonded to the TE-VCSEL die 204 by the one or more bonding layers 220.

The lens 304 may be arranged within the optical window 226 of the package casing 208 and arranged over the cavity 302. In addition, the lens 304 may be coupled to the fourth main surface 206b of the semiconductor substrate of the driver IC 206. For example, the lens 304 may be coupled to the fourth main surface 206b using a bonding material, such as an adhesive or gel.

The lens 304 may be configured to receive the light from the TE-VCSEL die 204 and transmit the light out of the package assembly 300. In some implementations, a diffractive optical element (DOE) 306 may be provided on an underside of the lens 304 to homogenize and/or focus laser light. In some implementations, the emitter array 210 may be configured to generate the light at a wavelength that is less than 1150 nm.

In some implementations, an anti-reflection coating 308 may be arranged on the lens 304. The anti-reflection coating 308 may be arranged in the light path area (e.g., in a light transmission path). The anti-reflection coating 308 may suppress or attenuate optical substrate modes due to multiple reflections, which may result in a cleaner optical spectral output and/or an optical output with lower noise.

As indicated above, FIG. 3 is provided as an example. Other examples may differ from what is described with regard to FIG. 3.

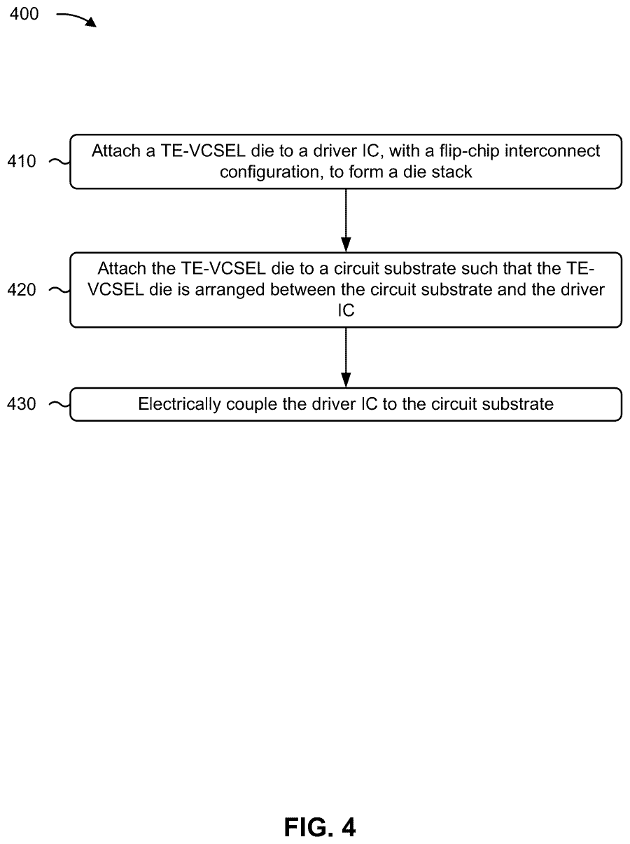

FIG. 4 is a flowchart of an example process 400 associated with fabricating a package assembly for a TE-VCSEL device. In some implementations, one or more process blocks of FIG. 4 are performed by a package assembly fabrication system.

As shown in FIG. 4, process 400 may include attaching a TE-VCSEL die to a driver IC (e.g., a driver die) to form a die stack (block 410). The process 400 may include manufacturing the TE-VCSEL die and the driver IC. For example, the TE-VCSEL die may include an emitter array comprising a plurality of VCSEL emitters, wherein the TE-VCSEL die comprises a first main surface and a second main surface arranged opposite to the first main surface, and wherein the TE-VCSEL die comprises an optical output arranged at the second main surface, the optical output configured to output light generated by one or more of the plurality of VCSEL emitters, wherein the driver IC is coupled to the second main surface of the TE-VCSEL die to form the die stack, wherein the driver IC has a flip-chip interconnect configuration, as described above.

As further shown in FIG. 4, process 400 may include attaching the TE-VCSEL die to a circuit substrate (block 420). The circuit substrate may include a first substrate surface and a second substrate surface arranged opposite to the first substrate surface, wherein the first main surface of the TE-VCSEL die is coupled to the first substrate surface of the circuit substrate such that the TE-VCSEL die is arranged between the circuit substrate and the driver IC, as described above.

As further shown in FIG. 4, process 400 may include electrically coupling the driver IC to the first substrate surface of the circuit substrate (block 430). The driver IC may include a semiconductor substrate comprising a third main surface coupled to the second main surface of the TE-VCSEL die, a fourth main surface arranged opposite to the third main surface, and driver circuitry integrated in the semiconductor substrate, wherein the driver IC includes a first plurality of conductive interconnect structures coupled to the third main surface, wherein the first plurality of conductive interconnect structures include a first subset of conductive interconnect structures electrically coupled to the driver circuitry and the plurality of VCSEL emitters, and a second subset of conductive interconnect structures electrically coupled to the driver circuitry and the circuit substrate, as described above.

Process 400 may include additional implementations, such as any single implementation or any combination of implementations described below and/or in connection with one or more other processes described elsewhere herein.

Although FIG. 4 shows example blocks of process 400, in some implementations, process 400 includes additional blocks, fewer blocks, different blocks, or differently arranged blocks than those depicted in FIG. 4. Additionally, or alternatively, two or more of the blocks of process 400 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, the term “component” is intended to be broadly construed as hardware, firmware, and/or a combination of hardware and software. It will be apparent that systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code-it being understood that software and hardware can be designed to implement the systems and/or methods based on the description herein.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A package assembly, comprising:
a circuit substrate comprising a first substrate surface and a second substrate surface arranged opposite to the first substrate surface;
a top-emitting (TE) vertical cavity surface emitting laser (VCSEL) die arranged on the first substrate surface of the circuit substrate, wherein the TE-VCSEL die comprises an emitter array comprising a plurality of VCSEL emitters that is two-dimensional (2D) matrix addressable, wherein the TE-VCSEL die comprises a first main surface and a second main surface, wherein the first main surface is coupled to the first substrate surface, and the second main surface is arranged opposite to the first main surface, and wherein the TE-VCSEL die comprises an optical output arranged at the second main surface, the optical output configured to output light generated by one or more of the plurality of VCSEL emitters; and
a driver integrated circuit (IC) arranged on and coupled to the second main surface of the TE-VCSEL die such that the TE-VCSEL die and the driver IC form a die stack on the first substrate surface of the circuit substrate, wherein the driver IC has a flip-chip interconnect configuration, and wherein the driver IC is electrically coupled to the TE-VCSEL die for individually driving each VCSEL emitter of the plurality of VCSEL emitters according to a 2D matrix address,
wherein the driver IC includes a driver substrate comprising a third main surface coupled to the second main surface of the TE-VCSEL die, a fourth main surface arranged opposite to the third main surface, and driver circuitry integrated in the driver substrate, wherein the driver IC includes a first plurality of conductive interconnect structures coupled to the third main surface, wherein the first plurality of conductive interconnect structures include a first subset of conductive interconnect structures electrically coupled to the driver circuitry and the plurality of VCSEL emitters, and a second subset of conductive interconnect structures electrically coupled to the driver circuitry and the circuit substrate.

2. The package assembly of claim 1, wherein the second subset of conductive interconnect structures are configured to receive power signals and emitter control signals from the circuit substrate.

3. The package assembly of claim 1, wherein the driver circuitry includes a digital control circuit configured to generate driving signals for driving the plurality of VCSEL emitters.

4. The package assembly of claim 1, further comprising:
conductive pillars coupled to the second subset of conductive interconnect structures and to the circuit substrate, wherein the conductive pillars extend between the circuit substrate and the driver IC.

5. The package assembly of claim 1, wherein the TE-VCSEL die includes a second plurality of conductive interconnect structures arranged at the second main surface of the TE-VCSEL die, and
wherein the second plurality of conductive interconnect structures are electrically coupled to the first subset of conductive interconnect structures.

6. The package assembly of claim 5, further comprising:
a bonding layer comprising an inorganic material, wherein the bonding layer is arranged over the emitter array between the TE-VCSEL die and the driver IC, and wherein the bonding layer is configured to bond the second main surface to the third main surface,
wherein the second plurality of conductive interconnect structures are coupled to the first subset of conductive interconnect structures by metal-to-metal bonding.

7. The package assembly of claim 1, further comprising:
a package casing disposed over the die stack, wherein the package casing is coupled to the fourth main surface of the driver IC, and wherein the package casing comprises an optical window configured to permit the light to exit the package assembly.

8. The package assembly of claim 7, wherein the driver substrate is optically transparent to the light, wherein the TE-VCSEL die is configured to transmit the light through a light path area of the driver substrate to the optical window.

9. The package assembly of claim 8, wherein the driver substrate includes a blank semiconductor region arranged over the emitter array in the light path area of the driver substrate, and
wherein the blank semiconductor region is a component-free region of raw semiconductor material configured to receive the light from the emitter array and pass the light to the optical window.

10. The package assembly of claim 8, wherein TE-VCSEL die is configured to generate the light at a wavelength of 1150 nanometer (nm) or greater.

11. The package assembly of claim 7, wherein the driver substrate includes a cavity that extends through the driver substrate between the third main surface and the fourth main surface, and
wherein the TE-VCSEL die is configured to transmit the light through the cavity to the optical window.

12. The package assembly of claim 11, further comprising:
a lens coupled to the fourth main surface and arranged within the optical window and over the cavity,
wherein the lens is configured to receive the light from the TE-VCSEL die and transmit the light out of the package assembly.

13. The package assembly of claim 11, wherein TE-VCSEL die is configured to generate the light at a wavelength that is less than 1150 nanometer (nm).

14. The package assembly of claim 1, wherein the TE-VCSEL die is configured to generate heat during operation,
wherein the TE-VCSEL die is thermally coupled to the circuit substrate, and
wherein the circuit substrate is configured to dissipate at least a portion of the heat.

15. The package assembly of claim 1, wherein the TE-VCSEL die is configured to generate heat during operation,
wherein the TE-VCSEL die is thermally coupled to the driver substrate and the circuit substrate,
wherein the driver substrate is configured to dissipate a first portion of the heat, and
wherein the circuit substrate is configured to dissipate a second portion of the heat.

16. The package assembly of claim 15, wherein the driver substrate includes a blank semiconductor region arranged over an entire area of the emitter array, and
wherein the blank semiconductor region is a component-free region configured to receive the first portion of heat and laterally distribute the first portion of heat toward edges of the driver substrate.

17. The package assembly of claim 16, wherein the blank semiconductor region is configured to distribute the first portion of heat away from the driver circuitry.

18. The package assembly of claim 1, further comprising:
at least one capacitor die comprising a plurality of capacitors,
wherein the driver IC comprises a second plurality of conductive interconnect structures coupled to the third main surface,
wherein the at least one capacitor die is coupled to the third main surface of the driver IC, and electrically coupled to the second plurality of conductive interconnect structures, and
wherein the plurality of capacitors are electrically coupled to the emitter array via the second plurality of conductive interconnect structures.

19. The package assembly of claim 1, wherein the package assembly is devoid of wire bonds.

20. A method, comprising:
attaching a top-emitting (TE) vertical cavity surface emitting laser (VCSEL) die to a driver integrated circuit (IC) to form a die stack,
wherein the TE-VCSEL die comprises an emitter array comprising a plurality of VCSEL emitters, wherein the TE-VCSEL die comprises a first main surface and a second main surface arranged opposite to the first main surface, and wherein the TE-VCSEL die comprises an optical output arranged at the second main surface, the optical output configured to output light generated by one or more of the plurality of VCSEL emitters,
wherein the driver IC is coupled to the second main surface of the TE-VCSEL die to form the die stack,
wherein the driver IC has a flip-chip interconnect configuration;
attaching the TE-VCSEL die to a circuit substrate comprising a first substrate surface and a second substrate surface arranged opposite to the first substrate surface,
wherein the first main surface of the TE-VCSEL die is coupled to the first substrate surface of the circuit substrate such that the TE-VCSEL die is arranged between the circuit substrate and the driver IC; and
electrically coupling the driver IC to the first substrate surface of the circuit substrate,
wherein the driver IC includes a driver substrate comprising a third main surface coupled to the second main surface of the TE-VCSEL die, a fourth main surface arranged opposite to the third main surface, and driver circuitry integrated in the driver substrate, wherein the driver IC includes a first plurality of conductive interconnect structures coupled to the third main surface, wherein the first plurality of conductive interconnect structures include a first subset of conductive interconnect structures electrically coupled to the driver circuitry and the plurality of VCSEL emitters, and a second subset of conductive interconnect structures electrically coupled to the driver circuitry and the circuit substrate.
